(19) United States
(12) Patent Application Publication
(10) Pub. No.: US 2024/0274608 A1
(43) Pub. Date: Aug. 15, 2024

(54) ARRAY SUBSTRATE AND DISPLAY DEVICE

(71) Applicant: TCL CHINA STAR OPTOELECTRONICS TECHNOLOGY CO., LTD., Shenzhen (CN)

(72) Inventor: Xiaoping YU, Shenzhen (CN)

(73) Assignee: TCL CHINA STAR OPTOELECTRONICS TECHNOLOGY CO., LTD., Shenzhen (CN)

(21) Appl. No.: 17/292,462

(22) PCT Filed: Apr. 19, 2021
(86) PCT No.: PCT/CN2021/088089

§ 371 Date: Apr. 30, 2024

(30) Foreign Application Priority Data
Jan. 29, 2021 (CN) 202110122863.6

(51) Int. Cl. H01L 27/12; G02F 1/1362

(52) U.S. Cl. CPC H01L 27/124; G02F 1/136222

(57) ABSTRACT

An array substrate includes a first metal layer and a second metal layer arranged on a substrate and electrically insulated from each other, the second metal layer arranged at one side of the first metal layer away from the substrate; and at least one functional conductive layer arranged on one side of at least one of the first metal layer or the second metal layer and arranged close to the substrate. An orthographic projection of the functional conductive layer projected on the substrate covers an orthographic projection of the second metal layer projected on the substrate, and the orthographic projection of the functional conductive layer projected on the substrate covers an orthographic projection of the first metal layer projected on the substrate.

### FIELD OF DISCLOSURE

The present application relates to a field of display technology and in particular, to an array substrate and a display device.

### DESCRIPTION OF RELATED ART

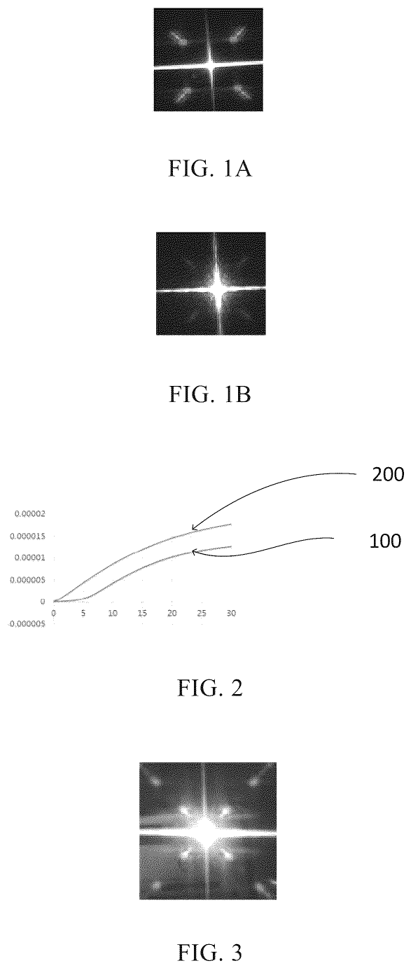

In recent years, people are more demanding of displays, so display manufacturers need to sell products which can satisfy an emerging demand for displays with wide color gamut, high contrast ratios, thinness, and narrow bezels. Four-sided borderless products are one of the development trends, and have broad prospects in the field of commercial displays or TV displays. There are currently two kinds of solutions for the four-sided borderless products: a color filter (CF) substrate side is arranged facing outwards and an array (TFT) substrate side is arranged facing outwards. The solution with the array substrate side facing outwards provides better integral appearance. However, the solution with the array substrate side facing outwards has a significant problem: under illumination of an external light source, a display has a serious rainbow mura problem which is more serious than a rainbow mura problem of the common solution with the color filter substrate side arranged facing outwards, which affects product performance. Please refer to FIGS. 1A and 1B. FIG. 1A is a schematic view illustrating a rainbow mura effect on a conventional color filter substrate side. FIG. 1B is a schematic view illustrating the rainbow mura effect on a conventional array substrate side. Wherein, the external light source includes natural light such as sunlight, fluorescent lamps, desk lamps, flashlights, and lights of mobile phones. Only when the external light source contains light with various wavelengths will the rainbow mura effect be caused. If the external light source is light with a single wavelength, it causes a single-color mura pattern (moiré pattern) on the array substrate side.

The rainbow mura effects are related to interference effects of light, and different film thicknesses are required for the interference effects of light of different wavelengths. A calculation formula for the film thickness with maximum interference intensity is: h=kλ/(2ncosi), wherein n represents a refractive index and k represents a light absorption coefficient. When light emitted by a point light source passes through a translucent film at different incident angles, suitable film thicknesses are provided for the light of different wavelengths, so a rainbow mura pattern appears. The rainbow mura pattern appears relatively more dispersed on the display with the array substrate side facing outwards. Analysis shows that this result is related to a metal layer such as source and drain of the TFT array substrate. When a transparent insulating film is placed under the metal layer, a condition is satisfied for the light of different wavelengths to produce the rainbow mura pattern. As shown in FIG. 2, FIG. 2 shows Id-Vd curves when a thickness is too great because a metal darkening layer is used in the metal layer, wherein a reference numeral 100 represents the Id-Vd curve when the metal layer has the metal darkening layer, and a reference numeral 200 represents the Id-Vd curve when the metal layer does not have the metal darkening layer. If a common metal darkening layer is used to reduce reflection of the metal layer, electrical properties of thin film transistors (TFTs) will be affected.

Therefore, in order to reduce a reflectivity of the metal layer to relieve the rainbow mura problem on the array substrate side facing outwards, there is an urgent need to provide a new array substrate and a new display device.

### SUMMARY OF INVENTION

### Technical Problem

The present application provides an array substrate and a display device. The present application comprises a functional conductive layer on at least one of a first metal layer or a second metal layer, an orthographic projection of the functional conductive layers projected on the substrate covers an orthographic projection of the second metal layer projected on the substrate, and the orthographic projection of the functional conductive layer projected on the substrate covers an orthographic projection of the first metal layer projected on the substrate. By adjusting thicknesses of the functional conductive layer and the first metal layer, and using an interference effect of light, the present application reduces a reflectivity of the second metal layer to an external light source, so as to relieve a rainbow mura problem on an array substrate side facing outward, and to improve quality of a display panel.

### Solution to Problem

### Technical Solution

In a first aspect, the present application provides an array substrate, comprising: a first metal layer and a second metal layer arranged on a substrate and electrically insulated from each other, wherein the second metal layer is arranged at one side of the first metal layer away from the substrate; and at least one functional conductive layer disposed on one side of at least one of the first metal layer or the second metal layer and arranged close to the substrate; wherein an orthographic projection of the at least one functional conductive layer projected on the substrate covers an orthographic projection of the second metal layer projected on the substrate; and the orthographic projection of the at least one functional conductive layer projected on the substrate covers an orthographic projection of the first metal layer projected on the substrate.

In a second aspect, the present application provides an array substrate, comprising: a first metal layer and a second metal layer disposed on a substrate and electrically insulated from each other, and the second metal layer is disposed at one side of the first metal layer away from the substrate; and a first functional conductive layer and a second functional conductive layer, wherein the first functional conductive layer is disposed on one side of the first metal layer close to the substrate, and the second functional conductive layer is disposed on one side of the second metal layer close to the substrate; wherein an orthographic projection of the second functional conductive layer projected on the substrate covers an orthographic projection of the second metal layer projected on the substrate; and an orthographic projection of the first functional conductive layer projected on the substrate covers an orthographic projection of the first metal layer projected on the substrate.

In some embodiments, an orthographic projection of the first functional conductive layer projected on the substrate covers an orthographic projection of the first metal layer projected on the substrate.

In a third aspect, the present application provides an array substrate, comprising: a first metal layer and a second metal layer arranged on a substrate and electrically insulated from each other, wherein the second metal layer is arranged at one side of the first metal layer away from the substrate; and at least one functional conductive layer disposed on one side of the first metal layer close to the substrate; wherein an orthographic projection of the at least one functional conductive layer projected on the substrate covers an orthographic projection of the second metal layer projected on the substrate; and the orthographic projection of the at least one functional conductive layer projected on the substrate covers an orthographic projection of the first metal layer projected on the substrate.

In some embodiments, the orthographic projection of the first metal layer projected on the substrate covers the orthographic projection of the second metal layer projected on the substrate.

In a fourth aspect, the present application provides an array substrate, comprising: a first metal layer and a second metal layer disposed on a substrate and electrically insulated from each other, wherein the second metal layer is disposed at one side of the first metal layer away from the substrate; at least one functional conductive layer disposed on one side of the first metal layer close to the substrate; and at least one metal conductive layer disposed on one side of the at least one functional conductive layer close to the first metal layer; wherein an orthographic projection of the at least one functional conductive layer projected on the substrate covers an orthographic projection of the second metal layer projected on the substrate; and the orthographic projection of the at least one functional conductive layer projected on the substrate covers an orthographic projection of the first metal layer projected on the substrate.

In some embodiments, the metal conductive layer is electrically insulated from the first metal layer.

In some embodiments, the orthographic projection of the at least one functional conductive layer projected on the substrate covers a total area of the orthographic projection of the first metal layer projected on the substrate and the orthographic projection of the second metal layer projected on the substrate.

In a fifth aspect, the present application provides an array substrate, comprising: a first metal layer and a second metal layer disposed on a substrate and electrically insulated from each other, wherein the second metal layer is disposed at one side of the first metal layer away from the substrate; and a functional conductive layer disposed on one side of the second metal layer close to the substrate; wherein an orthographic projection of the functional conductive layer projected on the substrate covers an orthographic projection of the second metal layer projected on the substrate. In some embodiments, the array substrate further comprises a gate insulating layer, the gate insulating layer is disposed on the first metal layer, the gate insulating layer covers the first metal layer and the substrate, and the second metal layer is disposed on one side of the gate insulating layer away from the first metal layer. In a sixth aspect, the present application provides an array substrate, comprising: a first metal layer and a second metal layer disposed on a substrate and electrically insulated from each other, wherein the second metal layer is disposed at one side of the first metal layer away from the substrate; and a plurality of functional conductive layers disposed on one side of at least one of the first metal layer or the second metal layer close to the substrate; wherein an orthographic projection of the functional conductive layers projected on the substrate covers an orthographic projection of the second metal layer projected on the substrate.

In some embodiments, the orthographic projection of the functional conductive layers projected on the substrate covers an orthographic projection of the first metal layer projected on the substrate.

In some embodiments, the functional conductive layers comprise a first functional conductive layer and a second functional conductive layer, the first functional conductive layer is disposed on one side of the first metal layer close to the substrate, the first functional conductive layer covers the first metal layer, the second functional conductive layer is disposed on one side of the second metal layer close to the substrate, and the second functional conductive layer covers the second metal layer.

In some embodiments, the functional conductive layers are disposed on one side of the first metal layer close to the substrate, and the functional conductive layers cover the first metal layer.

In some embodiments, the orthographic projection of the first metal layer projected on the substrate covers the orthographic projection of the second metal layer projected on the substrate.

In some embodiments, the array substrate further comprises a plurality of metal conductive layers, the functional conductive layers are disposed on one side of the first metal layer close to the substrate, the metal conductive layers are disposed on one side of the functional conductive layers close to the first metal layer, and the metal conductive layers are electrically insulated from the first metal layer.

In some embodiments, the orthographic projection of the functional conductive layers projected on the substrate covers a total area of the orthographic projection of the first metal layer projected on the substrate and the orthographic projection of the second metal layer projected on the substrate.

In some embodiments, the functional conductive layers are disposed on one side of the second metal layer close to the substrate, and the functional conductive layers cover the second metal layer.

In some embodiments, the array substrate further comprises a gate insulating layer, the gate insulating layer is disposed on the first metal layer, the gate insulating layer covers the first metal layer and the substrate, and the second metal layer is disposed on one side of the gate insulating layer away from the first metal layer.

The present application further provides a display device, comprising an array substrate, a color filter substrate disposed corresponding to the array substrate, and a liquid crystal layer disposed between the array substrate and the color filter substrate, the array substrate comprising: a first metal layer and a second metal layer disposed on a substrate and electrically insulated from each other, wherein the second metal layer is disposed at one side of the first metal layer away from the substrate; and at least one functional conductive layer disposed on one side of at least one of the first metal layer or the second metal layer close to the substrate; wherein an orthographic projection of the at least one functional conductive layer projected on the substrate covers an orthographic projection of the second metal layer projected on the substrate.

### Advantages of Invention

### Beneficial Effect

Compared with conventional techniques, in the array substrate and the display device of the present application, the array substrate comprises a first metal layer and a second metal layer electrically insulated from each other. A functional conductive layer is disposed on at least one of the first metal layer or the second metal layer. An orthographic projection of the functional conductive layers projected on the substrate covers an orthographic projection of the first metal layer projected on the substrate, so that the orthographic projection of the functional conductive layers projected on the substrate covers an orthographic projection of the second metal layer projected on the substrate. By adjusting thicknesses of the functional conductive layer and the first metal layer and using an interference effect of light, the present application reduces a reflectivity of the second metal layer to an external light source, thereby relieving a rainbow mura problem on an array substrate side facing outwards, and improving quality of a display panel. Furthermore, a work function of the functional conductive layer is close to a work function of a semiconductor layer, so that contact resistance between the functional conductive layer and the semiconductor layer can be maintained within a normal range, and as a result, electrical properties of the array substrate are not affected.

### BRIEF DESCRIPTION OF DRAWINGS

### Description of Attached Drawings

FIG. 1A is a schematic view illustrating a rainbow mura effect on a color filter substrate side in conventional techniques.

FIG. 1B is a schematic view illustrating the rainbow mura effect on an array substrate side in conventional techniques.

FIG. 2 shows Id-Vd curves in conventional techniques when a thickness is too large because a metal darkening layer is used in a second metal layer.

FIG. 3 is a schematic view illustrating the rainbow mura effect on the array substrate side after improvement.

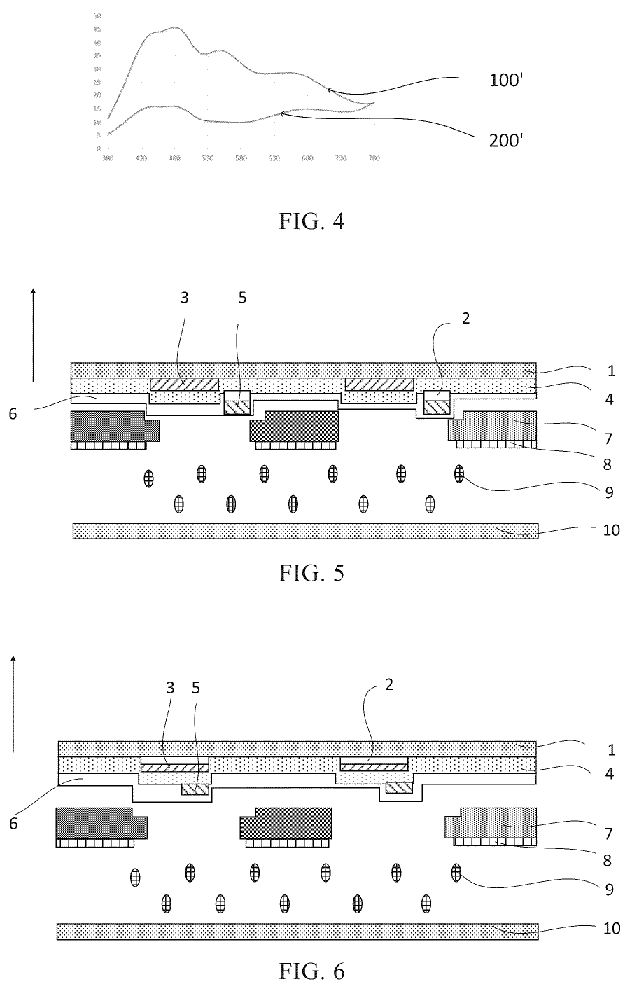

FIG. 4 shows reflectance spectrums before and after improvement.

FIG. 5 is a schematic structural view illustrating an array substrate according to one preferable embodiment of the present application.

FIG. 6 is a schematic structural view illustrating an array substrate according to another preferable embodiment of the present application.

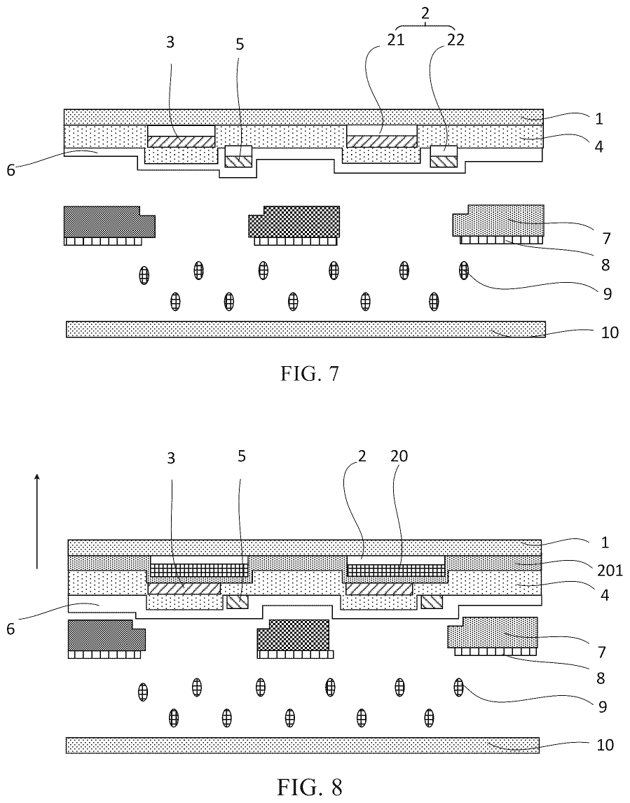

FIG. 7 is a schematic structural view illustrating an array substrate according to still another preferable embodiment of the present application.

FIG. 8 is a schematic structural view illustrating an array substrate according to other embodiments of the present application.

### EMBODIMENTS OF INVENTION

### Detailed Description of Preferred Embodiments

The present application provides an array substrate and a display device. In order to make the objectives, technical solutions, and effects of the present application clearer and specific, the present application will be further described in detail below with reference to the accompanying drawings and in conjunction with embodiments. Please be noted that the specific embodiments described here are only used to explain the present application, and are not used to limit the present application.

Referring to FIG. 5 to FIG. 8, an array substrate is provided according to one embodiment of the present application. The array substrate comprises a substrate 1, a first metal layer 3 disposed on the substrate 1, a second metal layer 5 disposed at one side of the first metal layer 3 away from the substrate 1, and a semiconductor layer (not shown in the drawing). The array substrate further comprises at least one functional conductive layer 2. In the present embodiment, the at least one functional conductive layer 2 is disposed on one side of at least one of the first metal layer 3 or the second metal layer 5 and arranged close to the substrate 1. An orthographic projection of the at least one functional conductive layer 2 projected on the substrate 1 covers an orthographic projection of the second metal layer 5 projected on the substrate 1. Preferably, in the present application, the semiconductor layer is disposed between the first metal layer 3 and the second metal layer 5. More preferably, the functional conductive layer 2 and the semiconductor layer have a same work function to reduce contact resistance between the functional conductive layer 2 and the semiconductor layer.

In the present application, an orthographic projection of the first metal layer 3 projected on the substrate 1 falls within an orthographic projection of the functional conductive layers 2 projected on the substrate 1.

Please refer to FIG. 7. In one most preferred embodiment, the functional conductive layers 2 comprises a first functional conductive layer 21 and a second functional conductive layer 22. The first functional conductive layer 21 is disposed on one side of the first metal layer 3 close to the substrate 1, the first functional conductive layer 21 covers the first metal layer 3, the second functional conductive layer 22 is disposed on one side of the second metal layer 5 close to the substrate 1, and the second functional conductive layer 22 covers the second metal layer 5. As shown in FIG. 7, an orthographic projection of the first functional conductive layer 21 projected on the substrate 1 completely coincides with the orthographic projection of the first metal layer 3 projected on the substrate 1. An orthographic projection of the second functional conductive layer 22 projected on the substrate 1 completely coincides with the orthographic projection of the second metal layer 5 projected on the substrate 1.

In a preferable embodiment of the present application, the functional conductive layer 2 is a transparent conductive layer, and a material of the functional conductive layer 2 is any one of indium tin oxide (ITO), indium zinc oxide (IZO), indium gallium zinc oxide (IGZO), and indium gallium zinc titanium oxide (IGZTO).

In a preferable embodiment of the present application, a material of the first metal layer 3 is at least one of copper (Cu), molybdenum (Mo), titanium (Ti), aluminum (Al), nickel (Ni), niobium (Nb), tantalum (Ta), or chromium (Cr).

In a preferable embodiment of the present application, a material of the second metal layer 5 is at least one of copper (Cu), molybdenum (Mo), titanium (Ti), aluminum (Al), nickel (Ni), niobium (Nb), tantalum (Ta), or chromium (Cr).

In the present embodiment, the functional conductive layer 2 is made of a material having a work function the same as the work function of the semiconductor layer, so as to reduce the contact resistance between the functional conductive layer 2 and the semiconductor layer. Since the functional conductive layer 2 (i.e., the first functional conductive layer 21 and the second functional conductive layer 22) and the semiconductor layer do not have a problem of excessively high contact resistance, electrical properties of the array substrate are not affected, and accordingly display performance is also not affected. Preferably, the first metal layer 3 is made of a material with good adhesion to the functional conductive layer 2 and the second metal layer 5, and the second metal layer 5 is made of a material having low resistivity, good conductivity, and low costs.

As shown in FIG. 7, the array substrate further comprises a gate insulating layer 4, the gate insulating layer 4 is disposed on the first metal layer 3, the gate insulating layer 4 covers the first metal layer 3 and the substrate 1, and the second metal layer 5 is disposed on one side of the gate insulating layer 4 away from the first metal layer 3. A material of the gate insulating layer 4 is silicon nitride (SiNx), or silicon oxide (SiOx), or silicon oxynitride (SiNxOy) to achieve a purpose of reducing reflection (anti-reflection) in a display area.

It needs to be particularly emphasized that a thickness of the first metal layer 3 is less than a skin depth d of the first metal layer 3 to ensure that light can penetrate the first metal layer 3, and reflect from a surface of the second metal layer 5. Wherein, the skin depth d of the first metal layer 3 is d=λ(4πnk), λ represents a wavelength, n and k represent an n value and a k value of the first metal layer 3, n represents a refractive index, and k represents a light absorption coefficient.

It should be noted that the first metal layer 3 and the second metal layer 5 are made of different materials.

In the present application, the first metal layer 3 is a gate, and the second metal layer 5 is a source and drain.

In one preferable embodiment, a material of the functional conductive layer 2 is preferably indium tin oxide (ITO), a material of the first metal layer 3 is preferably molybdenum (Mo), and a material of the second metal layer 5 is preferably copper (Cu). Wherein, a thickness of the functional conductive layer 2 ranges from 40 nm to 65 nm, and the thickness of the first metal layer 3 ranges from 5 nm to 20 nm. The thickness of the functional conductive layer 2 can be any value ranging from 40 nm to 65 nm, such as but not limited to 44 nm, 45 nm, 50 nm, 52 nm, 55 nm. The thickness of the first metal layer 3 can be any value ranging from 5 nm to 20 nm, such as but not limited to 5 nm, 6 nm, 10 nm, 11 nm, and 15 nm. Preferably, the thickness of the first metal layer 3 is 11 nm to ensure manufacturing process stability. In the present embodiment, as shown in FIG. 4, FIG. 4 shows reflectance spectrums of the array substrate before and after improvement, wherein 100′ represents the reflectance spectrum before improvement, and 200′ represents the reflectance spectrum after improvement. After improvement, a reflectivity of a composite electrode structure (i.e., an ITO/Mo/Cu structure) of the array substrate can be reduced to as low as about 13%. That is to say, the reflectivity of the ITO/Mo/Cu structure is reduced to a greater extent when compared to a reflectivity of about 45% of a Mo/Cu structure before improvement.

As shown in FIG. 7, the array substrate further comprises: a protective layer 6 disposed on the second metal layer 5, the protective layer 6 covering the second metal layer 5 and the gate insulating layer 4; multiple color resist blocks 7 arranged on the protective layer 6 at intervals and alternately arranged with thin film transistors of the array substrate; and a conductive layer 8. The conductive layer 8 is a disconnected structure, and is arranged on the color resist blocks 7. A material of the protective layer 6 is SiNx, and the protective layer 6 is configured to protect the second metal layer 5 from being corroded by photoresist during a manufacturing process.

The present application also provides a display device. As shown in FIG. 7, the display device comprises the array substrate, a color filter substrate 10 disposed on one side of the array substrate, and a liquid crystal layer 9 disposed between the array substrate and the color filter substrate 10. The liquid crystal layer 9 comprises multiple liquid crystals. The display device can be, but not limited to, a liquid crystal display device or an organic light emitting display device, and the display device can be a transparent display. In the present application, the display device is a liquid crystal display device.

In the present application, as shown in FIG. 7, an array substrate side faces outwards. That is to say, a backlight side of the display device is located on one side of the color filter substrate 10 facing away from the array substrate, and a light emitting side is located on one side of the array substrate facing away from the color filter substrate 10. A light emitting direction is in a direction from the backlight side to the light emitting side. That is to say, the light emitting side of the display panel is the array substrate side.

In the embodiment shown in FIG. 7, the functional conductive layers 2 are used to shield the first metal layer 3 and the second metal layer 5 at the same time. By adjusting the thicknesses of the functional conductive layer 2 and the first metal layer 3 and using an interference effect of light, the reflectivity of the second metal layer 5 to ambient light is reduced to relieve a rainbow mura pattern when the array substrate is arranged facing outwards, and accordingly the quality of the display panel is improved. Please refer to FIG. 3, which is a schematic view of the rainbow mura pattern on the array substrate side after improvement. It can be seen that, after improvement, the rainbow mura pattern on the array substrate side facing outwards has an equivalent performance to a performance of the rainbow mura pattern on a conventional color filter substrate side.

Please refer to FIG. 6. The present application further provides a preferable embodiment. The present embodiment is different from the embodiment shown in FIG. 7 in that the functional conductive layer 2 is disposed on one side of the first metal layer 3 close to the substrate 1 and covers the first metal layer 3, and the orthographic projection of the first metal layer 3 projected on the substrate 1 covers the orthographic projection of the second metal layer 5 projected on the substrate 1. As shown in FIG. 6, the orthographic projection of the functional conductive layer 2 projected on the substrate 1 completely coincides with the orthographic projection of the first metal layer 3 projected on the substrate 1.

The functional conductive layer 2 is configured to reduce reflection at a bottom of the first metal layer 3, and a bottom of the second metal layer 5 adopts a stacked structure of the first metal layer 3 and the functional conductive layer 2 to reduce reflection (anti-reflection).

Please refer to FIG. 8. The present application further provides a preferable embodiment. The present embodiment is different in that the functional conductive layer 2 is disposed on one side of the first metal layer 3 close to the substrate 1, and the array substrate further comprises at least one metal conductive layer 20. The metal conductive layer 20 is disposed on one side of the functional conductive layer 2 close to the first metal layer 3 and electrically insulated from the first metal layer 3. The metal conductive layer 20 covers the functional conductive layer 2, that is, an orthographic projection of the metal conductive layers 20 projected on the substrate 1 completely coincides with the orthographic projection of the functional conductive layer 2 projected on the substrate 1. As shown in FIG. 8, an interlayer insulating layer 201 is disposed on one side of the metal conductive layer 20 away from the functional conductive layers 2, and the interlayer insulating layer 201 covers the metal conductive layer 20 and the substrate 1. Preferably, a material of the metal conductive layers 20 is the same as the material of the first metal layer 3 or the second metal layer 5.

As shown in FIG. 8, a total area of the orthographic projection of the first metal layer 3 projected on the substrate 1 and the orthographic projection of the second metal layer 5 projected on the substrate 1 falls into an area of the orthographic projection of the functional conductive layers 2 projected on the substrate 1. In the present embodiment, the functional conductive layer 2 and at least one of the metal conductive layers 20 are stacked on the substrate 1 to form a composite film separately. The functional conductive layer 2 and at least one of the metal conductive layers 20 are configured to shield the first metal layer 3 and the second metal layer 5, so as to reduce reflectivities of metal film layers of the array substrate, that is, reducing the reflectivity of the first metal layer 3 and the second metal layer 5.

Please refer to FIG. 5. The present application further provides an embodiment. The present embodiment is different from the foregoing embodiment in that, as shown in FIG. 5, the functional conductive layer 2 is disposed on one side of the second metal layer 5 close to the substrate 1 and covers the second metal layer 5. As shown in FIG. 5, the orthographic projection of the functional conductive layer 2 projected on the substrate 1 completely coincides with the orthographic projection of the second metal layer 5 projected on the substrate 1. The functional conductive layer 2 is configured to reduce the reflectivity at the bottom of the second metal layer 5.

It should be noted that the anti-reflection effect on the second metal layer 5 of the array substrate in the embodiment of FIG. 6 is not as good as (slightly inferior to) the anti-reflection effect in the embodiment of FIG. 7. The anti-reflection effect on the metal film layers of the array substrate in the embodiment of FIG. 8 is not as good as the anti-reflection effect on the metal film layers of the array substrate in the embodiment of FIG. 6. The anti-reflection effect on the metal film layers of the array substrate in the embodiment of FIG. 5 is not as good as the anti-reflection effect of the metal film layers of the array substrate in the embodiment of FIG. 8. In detail, it is because the solution shown in FIG. 7 uses the first functional conductive layer 21 to reduce the reflection of the first metal layer 3, and uses the second functional conductive layer 22 to reduce the reflection of the second metal layer 5; the solution shown in FIG. 6 has a risk of an overlay shift between the first metal layer 3 and the second metal layer 5; the solution shown in FIG. 8 uses the functional conductive layer 2 and the metal conductive layer 20 as light-shielding layers, and a resulting thickness is not great enough, which slightly compromises the anti-reflection effect; and the solution shown in FIG. 5 only has the anti-reflection effect on the second metal layer 5, hence producing the worst anti-reflection effect.

In the present application, when the functional conductive layer 2 and the metal conductive layer 20 of the array substrate are used to reduce the reflectivity of the first metal layer 3, it is necessary to consider a film forming process such as temperatures and power of a physical vapor deposition (PVD) process, so as to prevent the functional conductive layer 2 from being etched uncleanly after crystallization. In addition, a film forming temperature for manufacturing the semiconductor layer is generally maintained at about 360° C., which causes a part of the functional conductive layer 2 to change its crystalline form, thereby affecting the anti-reflection effect on the first metal layer 3. Therefore, parameters of the film forming process need to be selected carefully.

In the array substrate and the display device of the present application, the array substrate comprises a first metal layer 3 and a second metal layer 5 electrically insulated from each other. A functional conductive layer 2 is disposed on at least one of the first metal layer 3 or the second metal layer 5. An orthographic projection of the functional conductive layer 2 projected on the substrate 1 covers an orthographic projection of the first metal layer 3 projected on the substrate 1, so that the orthographic projection of the functional conductive layers 2 projected on the substrate 1 covers an orthographic projection of the second metal layer 5 projected on the substrate 1. By adjusting thicknesses of the functional conductive layers 2 and the first metal layer 3 and using an interference effect of light, the present application reduces a reflectivity of the second metal layer 5 to an external light source, thereby relieving a problem of a rainbow mura pattern on the array substrate side facing outwards, and improving quality of a display panel. Furthermore, contact resistance between the functional conductive layer 2 and the semiconductor layer can be maintained within a normal range, so that electrical properties of the array substrate are not affected.

In the above-mentioned embodiments, the description of each embodiment has its own emphasis. For parts that are not described in detail in one embodiment, reference may be made to related descriptions of other embodiments. For the specific implementation of the above operations/solutions, please refer to the previous embodiment, and a detailed description is not repeated here.

It should be noted that for those of ordinary skill in the art, equivalent substitutions or changes can be made according to the technical solution and inventive concept of the present application, and all these changes or substitutions should fall within the protection scope of the appended claims of the present application.

What is claimed is:

1. An array substrate, comprising:
a first metal layer and a second metal layer arranged on a substrate and electrically insulated from each other, wherein the second metal layer is arranged at one side of the first metal layer away from the substrate; and
at least one functional conductive layer disposed on one side of at least one of the first metal layer or the second metal layer and arranged close to the substrate;
wherein an orthographic projection of the at least one functional conductive layer projected on the substrate covers an orthographic projection of the second metal layer projected on the substrate; and
the orthographic projection of the at least one functional conductive layer projected on the substrate covers an orthographic projection of the first metal layer projected on the substrate.

2. An array substrate, comprising:
a first metal layer and a second metal layer disposed on a substrate and electrically insulated from each other, and the second metal layer is disposed at one side of the first metal layer away from the substrate; and
a first functional conductive layer and a second functional conductive layer, wherein the first functional conductive layer is disposed on one side of the first metal layer close to the substrate, and the second functional conductive layer is disposed on one side of the second metal layer close to the substrate;
wherein an orthographic projection of the second functional conductive layer projected on the substrate covers an orthographic projection of the second metal layer projected on the substrate.

3. The array substrate according to claim 2, wherein an orthographic projection of the first functional conductive layer projected on the substrate covers an orthographic projection of the first metal layer projected on the substrate.

4. An array substrate, comprising:
a first metal layer and a second metal layer arranged on a substrate and electrically insulated from each other, wherein the second metal layer is arranged at one side of the first metal layer away from the substrate; and
at least one functional conductive layer disposed on one side of the first metal layer close to the substrate;
wherein an orthographic projection of the at least one functional conductive layer projected on the substrate covers an orthographic projection of the second metal layer projected on the substrate; and
the orthographic projection of the at least one functional conductive layer projected on the substrate covers an orthographic projection of the first metal layer projected on the substrate.

5. The array substrate according to claim 4, wherein the orthographic projection of the first metal layer projected on the substrate covers the orthographic projection of the second metal layer projected on the substrate.

6. An array substrate, comprising:
a first metal layer and a second metal layer disposed on a substrate and electrically insulated from each other, wherein the second metal layer is disposed at one side of the first metal layer away from the substrate;
at least one functional conductive layer disposed on one side of the first metal layer close to the substrate; and
at least one metal conductive layer disposed on one side of the at least one functional conductive layer close to the first metal layer;
wherein an orthographic projection of the at least one functional conductive layer projected on the substrate covers an orthographic projection of the second metal layer projected on the substrate; and
the orthographic projection of the at least one functional conductive layer projected on the substrate covers an orthographic projection of the first metal layer projected on the substrate.

7. The array substrate according to claim 6, wherein the metal conductive layer is electrically insulated from the first metal layer.

8. The array substrate according to claim 7, wherein the orthographic projection of the at least one functional conductive layer projected on the substrate covers a total area of the orthographic projection of the first metal layer projected on the substrate and the orthographic projection of the second metal layer projected on the substrate.

9. An array substrate, comprising:
a first metal layer and a second metal layer disposed on a substrate and electrically insulated from each other, wherein the second metal layer is disposed at one side of the first metal layer away from the substrate; and
a functional conductive layer disposed on one side of the second metal layer close to the substrate;
wherein an orthographic projection of the functional conductive layer projected on the substrate covers an orthographic projection of the second metal layer projected on the substrate.

10. The array substrate according to claim 9, wherein the array substrate further comprises a gate insulating layer, the gate insulating layer is disposed on the first metal layer, the gate insulating layer covers the first metal layer and the substrate, and the second metal layer is disposed on one side of the gate insulating layer away from the first metal layer.

11. An array substrate, comprising:
a first metal layer and a second metal layer disposed on a substrate and electrically insulated from each other, wherein the second metal layer is disposed at one side of the first metal layer away from the substrate; and
a plurality of functional conductive layers disposed on one side of at least one of the first metal layer or the second metal layer close to the substrate;
wherein an orthographic projection of the functional conductive layers projected on the substrate covers an orthographic projection of the second metal layer projected on the substrate.

12. The array substrate according to claim 11, wherein the orthographic projection of the functional conductive layers projected on the substrate covers an orthographic projection of the first metal layer projected on the substrate.

13. The array substrate according to claim 12, wherein the functional conductive layers comprise a first functional conductive layer and a second functional conductive layer, the first functional conductive layer is disposed on one side of the first metal layer close to the substrate, the first functional conductive layer covers the first metal layer, the second functional conductive layer is disposed on one side of the second metal layer close to the substrate, and the second functional conductive layer covers the second metal layer.

14. The array substrate according to claim 12, wherein the functional conductive layers are disposed on one side of the first metal layer close to the substrate, and the functional conductive layers cover the first metal layer.

15. The array substrate according to claim 14, wherein the orthographic projection of the first metal layer projected on the substrate covers the orthographic projection of the second metal layer projected on the substrate.

16. The array substrate according to claim 12, wherein the array substrate further comprises a plurality of metal conductive layers, the functional conductive layers are disposed on one side of the first metal layer close to the substrate, the metal conductive layers are disposed on one side of the functional conductive layers close to the first metal layer, and the metal conductive layers are electrically insulated from the first metal layer.

17. The array substrate according to claim 16, wherein the orthographic projection of the functional conductive layers projected on the substrate covers a total area of the orthographic projection of the first metal layer projected on the substrate and the orthographic projection of the second metal layer projected on the substrate.

18. The array substrate according to claim 11, wherein the functional conductive layers are disposed on one side of the second metal layer close to the substrate, and the functional conductive layers cover the second metal layer.

19. The array substrate according to claim 11, wherein the array substrate further comprises a gate insulating layer, the gate insulating layer is disposed on the first metal layer, the gate insulating layer covers the first metal layer and the substrate, and the second metal layer is disposed on one side of the gate insulating layer away from the first metal layer.

20. A display device, comprising an array substrate, a color filter substrate disposed corresponding to the array substrate, and a liquid crystal layer disposed between the array substrate and the color filter substrate, the array substrate comprising:
a first metal layer and a second metal layer disposed on a substrate and electrically insulated from each other, wherein the second metal layer is disposed at one side of the first metal layer away from the substrate; and
at least one functional conductive layer disposed on one side of at least one of the first metal layer or the second metal layer close to the substrate;
wherein an orthographic projection of the at least one functional conductive layer projected on the substrate covers an orthographic projection of the second metal layer projected on the substrate.
